(19) United States
(12) Patent Application Publication
(10) Pub. No.: US 2011/0215328 A1
(43) Pub. Date: Sep. 8, 2011

(54) THIN FILM TRANSISTOR, METHOD OF MANUFACTURING THE THIN FILM TRANSISTOR, AND DISPLAY DEVICE

(75) Inventors: Narihiro Morosawa, Kanagawa (JP); Takashige Fujimori, Kanagawa (JP); Toshiaki Arai, Kanagawa (JP)

(73) Assignee: SONY CORPORATION, Tokyo (JP)

(21) Appl. No.: 13/037,441

(22) Filed: Mar. 1, 2011

(30) Foreign Application Priority Data
Mar. 4, 2010 (JP) P2010-048306

(51) Int. Cl. H01L 29/786; H01L 21/336

(52) U.S. Cl. 257/59; 257/57; 438/158; 257/E29.273; 257/E21.411

(57) ABSTRACT

There is provided a thin film transistor, which has a uniform and good electric characteristic and has a simple configuration allowing decrease in number of manufacturing steps, and a method of manufacturing the thin film transistor, and a display device having the thin film transistor. The thin film transistor includes: a gate electrode; an oxide semiconductor film having a multilayer structure of an amorphous film and a crystallized film; and a source electrode and a drain electrode provided to contact the crystallized film.

### CROSS REFERENCES TO RELATED APPLICATIONS

The present application claims priority to Japanese Priority Patent Application JP 2010-048306 filed in the Japan Patent Office on Mar. 4, 2010, the entire content of which is hereby incorporated by reference.

### BACKGROUND

The present application relates to a thin film transistor (TFT) using oxide semiconductor, a method of manufacturing the thin film transistor, and a display device having the thin film transistor.

Oxide semiconductor such as zinc oxide (ZnO) or indium-gallium-zinc oxide (IGZO) has an excellent property for an active layer of a semiconductor device, and is recently increasingly developed to be used for TFT, a light emitting device, and a transparent conductive film.

For example, TFT using the oxide semiconductor has large electron mobility, and thus has an excellent electric property compared with previous TFT using amorphous silicon (a-Si: H) for a channel, which has been used for a liquid crystal display device. In addition, the TFT using the oxide semiconductor is advantageously expected to have high mobility even if a channel is deposited at low temperature near room temperature.

For example, it is known that TFT using an amorphous oxide semiconductor film such as IGZO film as a channel has a uniform electric characteristic (for example, see Japanese Unexamined Patent Application Publication No. 2009-99847, paragraph 0047).

### SUMMARY

However, the amorphous oxide semiconductor film is low in resistance to chemicals, and therefore wet etching has been hard to be used for etching of a film formed on the oxide semiconductor film.

For example, a-Si TFT generally uses a structure called channel etch type where source and drain electrodes are directly disposed on a non-doped a-Si film and a phosphor-doped a-Si film to be a channel without forming an etching stopper film. In a manufacturing process of such a channel-etch-type TFT, for example, since etching selectivity of the source and drain electrodes to phosphor-doped a-Si may be made adequately high, only the source and drain electrodes may be selectively etched in wet etching. The phosphor-doped and non-doped a-Si films are subsequently etched, so that the channel-etch-type TFT may be formed. Therefore, for a-Si TFT, the channel etch type may be used, which eliminates need of the etching stopper layer, and therefore a simple configuration is achieved, leading to decrease in number of manufacturing steps.

When such a channel-etch-type structure is used for TFT using oxide semiconductor, while the oxide semiconductor film under the source and drain electrodes is also etched during an etching step of the electrodes, a portion of the oxide semiconductor film to be a channel needs to be left. Thus, thickness of the oxide semiconductor film needs to be relatively large, about 200 nm.

However, it has been seen that when thickness of the oxide semiconductor film is increased to a certain thickness or larger, an electric characteristic of TFT is degraded, and besides deposition time of the oxide semiconductor film increases. Therefore, actually, the channel-etch-type has been hardly used for TFT using the oxide semiconductor unlike amorphous silicon TFT.

It is likely that oxide semiconductor such as zinc oxide (ZnO), IZO (indium-zinc oxide) or IGO (indium-gallium oxide), which is easily crystallized in a relatively low temperature process, is used for a channel. However, TFT using a crystallized oxide semiconductor film as a channel has been hard to have a uniform electric characteristic because of defects caused by crystal grain boundaries.

It is desirable to provide a thin film transistor, which has a uniform and good electric characteristic and has a simple configuration allowing decrease in number of manufacturing steps, and a method of manufacturing the thin film transistor, and a display device having the thin film transistor.

A thin film transistor according to an embodiment includes a gate electrode, an oxide semiconductor film having a multilayer structure of an amorphous film and a crystallized film, and a source electrode and a drain electrode provided to contact the crystallized film.

In the thin film transistor according to the embodiment, since the oxide semiconductor film has the multilayer structure of the amorphous film and the crystallized film, a highly uniform electric characteristic is secured by the amorphous film. Moreover, since the source electrode and the drain electrode are provided to contact the crystallized film, etching of the oxide semiconductor film is suppressed when an upper layer, including the source electrode and the drain electrode or an etching stopper layer, is etched in a manufacturing process. Accordingly, thickness of the oxide semiconductor film need not be increased, leading to a good electric characteristic.

A first method of manufacturing a thin film transistor according to an embodiment includes the following steps (A) to (E);

(A) forming a gate electrode on a substrate,

(B) forming a gate insulating film on the gate electrode,

(C) forming a multilayer film of an amorphous film including an oxide semiconductor and a crystallized film including an oxide semiconductor in this order on the gate insulating film,

(D) shaping the multilayer film by etching to form an oxide semiconductor film having a multilayer structure of the amorphous film and the crystallized film, and

(E) forming a metal film on the crystallized film, and etching the metal film to form a source electrode and a drain electrode.

A second method of manufacturing a thin film transistor according to an embodiment includes the following steps (A) to (F);

(A) forming a gate electrode on a substrate,

(B) forming a gate insulating film on the gate electrode,

(C) forming a multilayer film of an amorphous film including an oxide semiconductor and a low-melting point amorphous film, including an oxide semiconductor having a lower melting point than that of the amorphous film, in this order on the gate insulating film,

(D) shaping the multilayer film by etching,

(E) annealing the low-melting point amorphous film to be formed into a crystallized film so as to form an oxide semiconductor film having a multilayer structure of the amorphous film and the crystallized film, and

(F) forming a metal film on the crystallized film, and etching the metal film to form a source electrode and a drain electrode.

A display device according to an embodiment includes thin film transistors and pixels, and each thin film transistor is configured of the thin film transistor according to the embodiment.

In the display device according to the embodiment, each pixel is driven by the thin film transistor according to the embodiment for image display.

According to the thin film transistor of the embodiment, since the oxide semiconductor film has the multilayer structure of the amorphous film and the crystallized film, a uniform electric characteristic may be achieved. Moreover, since the source electrode and the drain electrode are provided to contact the crystallized film, etching of the oxide semiconductor film is suppressed when an upper layer is etched in a manufacturing process, and therefore thickness of the oxide semiconductor film need not be increased, and consequently a good electric characteristic may be obtained. Accordingly, when the thin film transistor is used to configure a display device, uniform and good display may be achieved.

According to the first method of manufacturing a thin film transistor of the embodiment, an oxide semiconductor film having a multilayer structure of an amorphous film and a crystallized film is formed, and then a metal film is formed on the crystallized film, and the metal film is etched to form a source electrode and a drain electrode, and therefore when the channel etch type is used, wet etching selectivity of the source and drain electrodes to the oxide semiconductor film may be made high. Accordingly, a simple channel-etch-type configuration may be used, leading to decrease in number of manufacturing steps.

According to the second method of manufacturing a thin film transistor of the embodiment, since a multilayer film of an amorphous film including an oxide semiconductor and a low-melting point amorphous film, including an oxide semiconductor having a lower melting point than that of the amorphous film, is formed, and then the multilayer film is shaped by etching, the multilayer film may be easily processed into a predetermined shape by inexpensive wet etching. Moreover, the low-melting point amorphous film is annealed to be formed into a crystallized film, so that an oxide semiconductor film having a multilayer structure of the amorphous film and the crystallized film is formed, and then a metal film is formed on the crystallized film, and the metal film is etched to form a source electrode and a drain electrode. Therefore, when the channel etch type is used, wet etching selectivity of the source and drain electrodes to the oxide semiconductor film may be made high. Accordingly, a simple channel-etch-type configuration may be used, leading to decrease in number of manufacturing steps.

Additional features and advantages are described herein, and will be apparent from the following Detailed Description and the figures.

### BRIEF DESCRIPTION OF THE FIGURES

FIG. 1 is a sectional diagram showing a structure of a thin film transistor according to a first embodiment.

FIGS. 2A to 2C are sectional diagrams showing a method of manufacturing the thin film transistor shown in FIG. 1 in a step sequence.

FIGS. 3A and 3B are sectional diagrams showing steps following FIG. 2C.

FIGS. 4A to 4D are sectional diagrams showing a method of manufacturing a thin film transistor according to a second embodiment in a step sequence.

FIGS. 5A to 5C are sectional diagrams showing steps following FIG. 4D.

FIG. 6 is a sectional diagram showing a configuration of a thin film transistor according to a third embodiment.

FIGS. 7A to 7D are sectional diagrams showing a method of manufacturing the thin film transistor shown in FIG. 6 in a step sequence.

FIG. 8 is a sectional diagram showing a structure of a thin film transistor according to a fourth embodiment.

FIGS. 9A to 9C are sectional diagrams showing a method of manufacturing the thin film transistor shown in FIG. 7 in a step sequence.

FIGS. 10A to 10D are sectional diagrams showing steps following FIG. 9C.

FIG. 11 is a diagram showing a circuit configuration of a display device according to application example 1.

FIG. 12 is an equivalent circuit diagram showing an example of a pixel drive circuit shown in FIG. 11.

FIG. 13 is a perspective diagram showing appearance of application example 2.

FIGS. 14A and 14B are perspective diagrams, where FIG. 14A shows appearance of application example 3 as viewed from a surface side, and FIG. 14B shows appearance thereof as viewed from a back side.

FIG. 15 is a perspective diagram showing appearance of application example 4.

FIG. 16 is a perspective diagram showing appearance of application example 5.

FIGS. 17A to 17G are diagrams of application example 6, where FIG. 17A is a front diagram of the application example 6 in an opened state, FIG. 17B is a side diagram thereof, FIG. 17C is a front diagram thereof in a closed state, FIG. 17D is a left side diagram thereof, FIG. 17E is a right side diagram thereof, FIG. 17F is a top diagram thereof, and FIG. 17G is a bottom diagram thereof.

### DETAILED DESCRIPTION

Embodiments of the present application will be described below in detail with reference to the drawings.

1. First embodiment (bottom-gate thin film transistor; channel etch type; example of a manufacturing method, where a multilayer film of an amorphous film and a crystallized film is formed, and the multilayer film is processed by etching).

2. Second embodiment (bottom-gate thin film transistor; channel etch type; example of a manufacturing method, where a multilayer film of an amorphous film and a low-melting point amorphous film is formed, and the multilayer film is processed by etching and then the low-melting point amorphous film is annealed to be formed into a crystallized film)

3. Third embodiment (bottom-gate thin film transistor; etching stopper type)

4. Fourth embodiment (top-gate thin film transistor)

5. Application examples

### FIRST EMBODIMENT

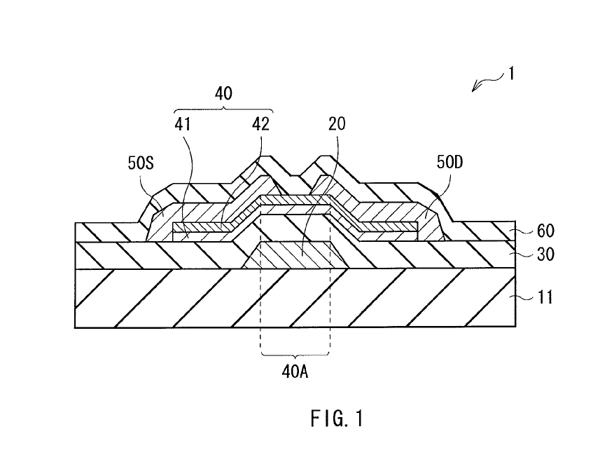

FIG. 1 shows a sectional structure of a thin film transistor 1 according to a first embodiment. The thin film transistor 1 is used as a drive element of a liquid crystal display or an organic EL (Electro Luminescence) display, and, for example, has a bottom-gate (inversely staggered) configuration where a gate electrode 20, a gate insulating film 30, an oxide semiconductor film 40, a source electrode 50S and a drain electrode 50D, and a protective film 60 are stacked in this order on a substrate 11. The oxide semiconductor film 40 has a channel region 40A facing the gate electrode 20, and respective ends of the source and drain electrodes 50S and 50D are provided on the channel region 40A. In other words, the thin film transistor 1 is a channel-etch-type transistor.

The substrate 11 is configured of a glass substrate, a plastic film or the like. Materials of the plastic film include, for example, PET (polyethylene terephthalate) and PEN (polyethylene naphthalate). Since the oxide semiconductor film 40 is deposited without heating the substrate 11 by a sputtering method described later, an inexpensive plastic film may be used.

The gate electrode 20 applies a gate voltage to the thin film transistor 1 to control electron density in the oxide semiconductor film 40 by the gate voltage. The gate electrode 20, which is provided in a selective region on the substrate 11, has a thickness of, for example, 10 nm to 500 nm, and is configured of simple metal or metal alloy including one or more selected from a group consisting of platinum (Pt), titanium (Ti), ruthenium (Ru), molybdenum (Mo), copper (Cu), tungsten (W) and nickel (Ni).

The gate insulating film 30, having a thickness of, for example, 50 nm to 1 μm, and is configured of a single-layer film of a silicon oxide film, a silicon nitride film, a silicon oxynitride film, or an aluminum oxide film or a multilayer film of the films.

The oxide semiconductor film 40 is provided, for example, in an island shape including the gate electrode 20 and the neighborhood thereof, and disposed to have a channel region 40A between the source electrode 50S and the drain electrode 50D. The oxide semiconductor film 40 is configured of transparent oxide semiconductor mainly containing zinc oxide, for example, IGZO (indium-gallium-zinc oxide), zinc oxide, IZO, IGO, AZO (aluminum-doped zinc oxide) or GZO (gallium-doped zinc oxide). Here, the oxide semiconductor means compounds containing an element such as indium, gallium, zinc or tin and oxygen.

The oxide semiconductor film 40 has a multilayer structure of an amorphous film 41 and a crystallized film 42. The source electrode 50S and the drain electrode 50D are provided to contact the crystallized film 42. Specifically, the oxide semiconductor film 40 has a multilayer structure where the amorphous film 41 and the crystallized film 42 are stacked in this order from the gate electrode 20 side. Consequently, the thin film transistor 1 may have a uniform and good electric characteristic.

The amorphous film 41, which functions as a channel of the thin film transistor 1, is provided on the gate electrode 20 side of the oxide semiconductor film 40. The amorphous film 41 having a thickness of, for example, about 10 nm to 50 nm, is configured of amorphous oxide semiconductor such as IGZO.

The crystallized film 42, which secures etching selectivity to an upper layer in a manufacturing process, is provided on a side near the source and drain electrodes 50S and 50D of the oxide semiconductor film 40. The crystallized film 42 having a thickness of, for example, about 10 nm to 50 nm, is configured of crystallized oxide semiconductor such as zinc oxide, IZO or IGO.

Thickness of the oxide semiconductor film 40 (total thickness of the amorphous film 41 and the crystallized film 42) is desirably, for example, about 20 nm to 100 nm in the light of efficiency of oxygen supply during anneal in a manufacturing process.

The source and drain electrodes 50S and 50D are configured of, for example, a metal film including molybdenum, aluminum, copper or titanium, an oxygen-contained metal film including ITO (Indium Tin Oxide) or titanium oxide, or a multilayer film of the films. Specifically, the source or drain electrode 50S or 50D has, for example, a structure where a molybdenum layer with a thickness of 50 nm, an aluminum layer with a thickness of 500 nm, and a molybdenum layer with a thickness of 50 nm are sequentially stacked.

The source and drain electrodes 50S and 50D are preferably configured of the oxygen-contained metal film including ITO, titanium oxide or the like. When the oxide semiconductor film 40 contacts a metal having strong affinity for oxygen, oxygen may be detached from the film 40, leading to formation of lattice defects in the film. Thus, the source and drain electrodes 50S and 50D are configured of the oxygen-contained metal film, which may prevent oxygen from being detached from the oxide semiconductor film 40, leading to stabilization of an electric characteristic of the thin film transistor 1.

The protective film 60 is configured of, for example, a single-layer film of an aluminum oxide film, a silicon oxide film or silicon nitride film, or a multilayer film of the films. In particular, the aluminum oxide film is preferable. The aluminum oxide film may act as a protective film 60 having high barrier performance, and therefore the film may suppress change in electric characteristic of the oxide semiconductor film 40 due to water absorption, leading to stabilization of the electric characteristic of the oxide semiconductor film 40. In addition, the protective film 60 including the aluminum oxide film may be deposited without degrading the characteristic of the thin film transistor 1. Furthermore, an aluminum oxide film having high density is used, so that the barrier performance of the protective film 60 may be further improved, leading to suppression of adverse effects of hydrogen or water causing degradation of the electric characteristic of the oxide semiconductor film 40.

The thin film transistor 1 may be manufactured, for example, in the following way.

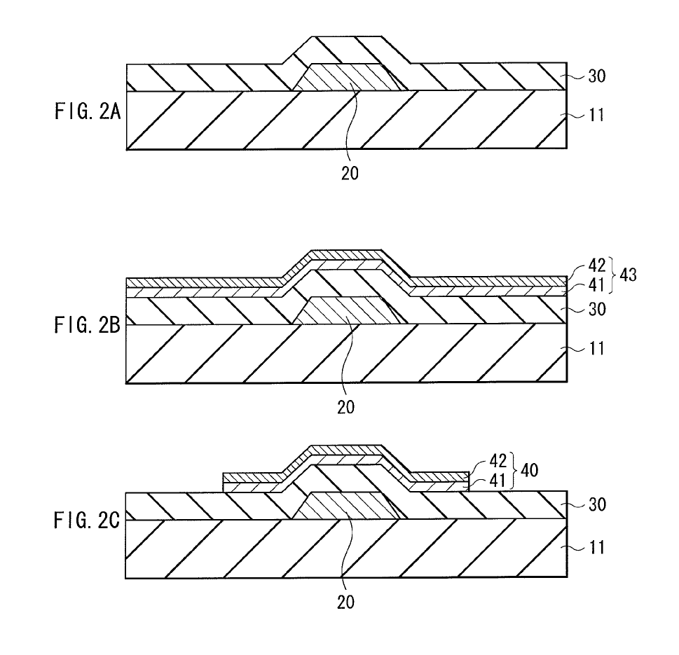

FIGS. 2A to 2C show a method of manufacturing the thin film transistor 1 in a step sequence. First, a metal film as a material of the gate electrode 20 is formed over the whole surface on the substrate 11 by, for example, a sputtering method or an evaporation method. Next, as shown in FIG. 2A, the metal film formed on the substrate 11 is patterned by, for example, photolithography and etching processes to form the gate electrode 20.

Next, as shown in FIG. 2A, the gate insulating film 30 including, for example, a multilayer film of a silicon nitride film and a silicon oxide film is formed over the whole surface on the substrate 11 and on the gate electrode 20 by, for example, a plasma CVD (Chemical Vapor Deposition) method or a sputtering method.

Specifically, the silicon nitride film is formed by a plasma CVD method using a gas such as silane, ammonia and nitrogen as a source gas, and the silicon oxide film is formed by a plasma CVD method using a gas containing silane and dinitrogen monoxide as a source gas.

After the gate insulating film 30 is formed, as shown in FIG. 2B, the amorphous film 41, of which the thickness and the material are as described before, is formed by, for example, a sputtering method. Specifically, for example, an amorphous film 41 made of IGZO is formed on the gate insulating film 30 by plasma discharge using a mixed gas of argon and oxygen by means of a DC sputter method with IGZO ceramics as a target. A vacuum chamber (not shown) is evacuated to an inner vacuum degree of 1×10-4 Pa or lower before the plasma discharge, and then the mixed gas of argon and oxygen is introduced.

Carrier concentration in the amorphous film 41 to be a channel may be controlled by changing a flow ratio between argon and oxygen during oxide formation.

After the amorphous film 41 is formed, as shown in FIG. 2B, the crystallized film 42, of which the thickness and the material are as described before, is formed by, for example, a sputtering method. Specifically, for example, a crystallized film 42 made of IZO is formed by a DC sputtering method with IZO ceramics as a target.

In this way, the multilayer film 43 of the amorphous film 41 and the crystallized film 42 is formed.

After the multilayer film 43 is formed, as shown in FIG. 2C, the multilayer film 43 is formed into a predetermined shape, for example, an island shape including the gate electrode 20 and the neighborhood thereof by, for example, photolithography and etching. Consequently, the oxide semiconductor film 40 having the multilayer structure of the amorphous film 41 and the crystallized film 42 is formed.

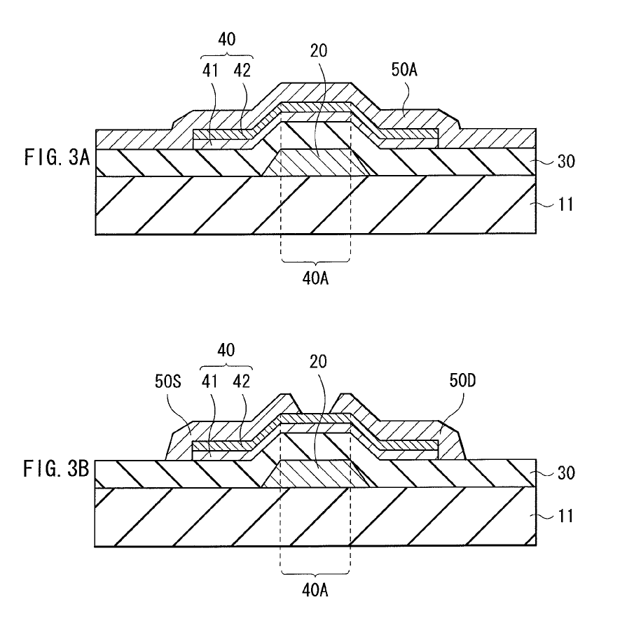

After the oxide semiconductor film 40 is formed, as shown in FIG. 3A, a molybdenum layer with a thickness of 50 nm, an aluminum layer with a thickness of 500 nm and a molybdenum layer with a thickness of 50 nm are sequentially formed on the crystallized layer 42 of the oxide semiconductor film 40 by, for example, a sputtering method, and thus a metal film 50A having a three-layer multilayer structure is formed.

Next, the metal film 50A having the multilayer structure is patterned by a wet etching method using a mixed solution containing phosphoric acid, nitric acid and acetic acid, and thus the source electrode 50S and the drain electrode 50D are formed as shown in FIG. 3B. Since the source electrode 50S and the drain electrode 50D (metal film 50A) are provided on the crystallized film 42, wet etching selectivity of the source and drain electrodes 50S and 50D (metal film 50A) to the oxide semiconductor film 40 is high. Accordingly, the source electrode 50S and the drain electrode 50D may be selectively etched while etching of the oxide semiconductor film 40 is suppressed.

After the source electrode 50S and the drain electrode 50D are formed, the protective film 60 made of the above material is formed by, for example, a plasma CVD method or a sputtering method. This is the end of manufacturing of the thin film transistor 1 shown in FIG. 1.

In the thin film transistor 1, when a voltage (gate voltage) equal to or higher than a predetermined threshold voltage is applied to the gate electrode 20 through a not-shown wiring layer, a current (drain current) is generated in the channel region 40A of the oxide semiconductor film 40. Since the oxide semiconductor film 40 has the multilayer structure of the amorphous film 41 and the crystallized film 42, a highly uniform electric characteristic is secured by the amorphous film 41. In addition, since the source electrode 50S and the drain electrode 50D are provided to contact the crystallized film 42, when the source electrode 50S and the drain electrode 50D are etched in a manufacturing process, etching of the oxide semiconductor film 40 is suppressed. Accordingly, thickness of the oxide semiconductor film 40 need not be increased, leading to a good electric characteristic.

In this way, in the thin film transistor 1 of the embodiment, since the oxide semiconductor film 40 has the multilayer structure of the amorphous film 41 and the crystallized film 42, a highly uniform electric characteristic may be obtained by the amorphous film 41. In addition, since the source electrode 50S and the drain electrode 50D are provided to contact the crystallized film 42, when the source electrode 50S and the drain electrode 50D are etched in a manufacturing process, etching of the oxide semiconductor film 40 may be suppressed. Accordingly, thickness of the oxide semiconductor film 40 need not be increased, leading to a good electric characteristic.

In the method of manufacturing the thin film transistor 1 of the embodiment, the oxide semiconductor film 40 having the multilayer structure of the amorphous film 41 and the crystallized film 42 is formed, and then the metal film 50A is formed on the crystallized film 42, and the metal film 50A is etched to form the source electrode 50S and the drain electrode 50D. Therefore, when a channel etch type is used, wet etching selectivity of the source and drain electrodes 50S and 50D to the oxide semiconductor film 40 may be made high. Accordingly, the thin film transistor may use a simple channel-etch-type configuration, leading to decrease in number of manufacturing steps. Moreover, since thickness of the oxide semiconductor film 40 need not be increased, deposition time and cost may be reduced.

### SECOND EMBODIMENT

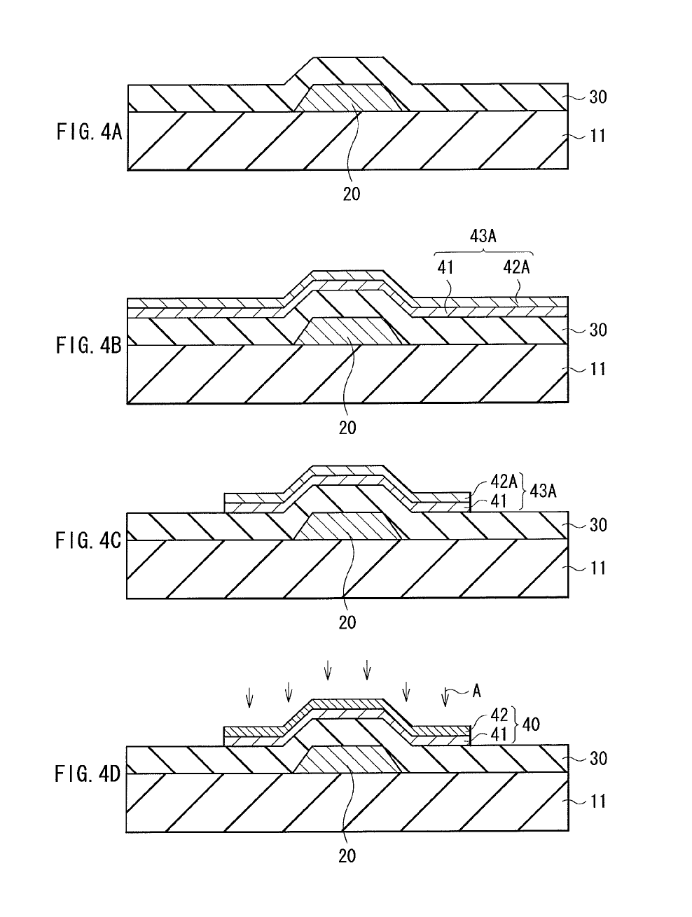

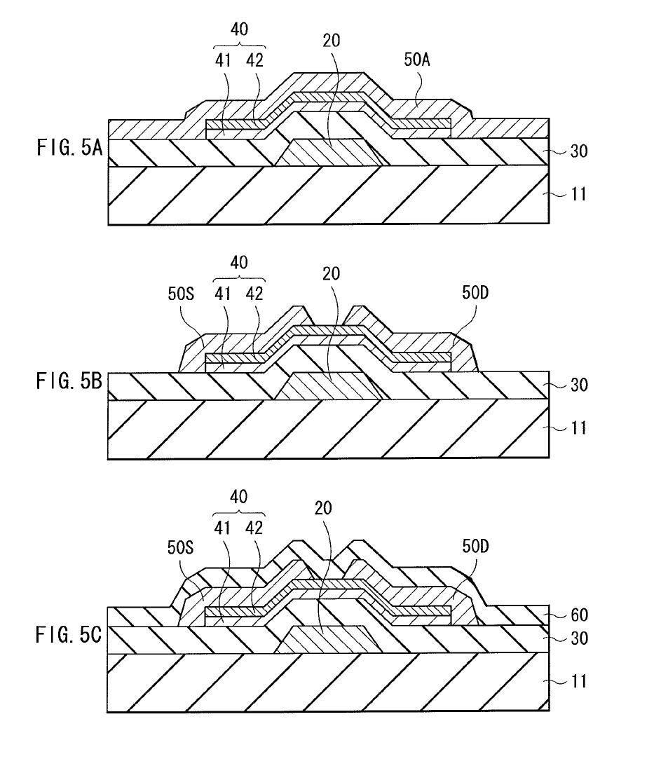

FIGS. 4A to 4D and 5A to 5C show a method of manufacturing a thin film transistor 1 according to a second embodiment in a step sequence. The method is different from the method of the first embodiment in that a multilayer film of an amorphous film and a low-melting point amorphous film is formed, the multilayer film is processed by etching, and then the low-melting point amorphous film is annealed to be formed into a crystallized film. Therefore, the same steps as in the first embodiment are described with reference to FIGS. 2A to 2C and FIGS. 3A and 3B.

First, as shown in FIG. 4A, a gate electrode 20 and a gate insulating film 30 are sequentially formed on a substrate 11 in the same way as in the first embodiment.

Next, as shown in FIG. 4B, an amorphous film 41, of which the thickness and the material are as described before, is formed by, for example, a sputtering method. Specifically, for example, an amorphous film 41 made of IGZO is formed on the gate insulating film 30 by plasma discharge using a mixed gas of argon and oxygen by means of a DC sputtering method with IGZO ceramics as a target. A vacuum chamber (not shown) is evacuated to an inner vacuum degree of 1×10-4 Pa or lower before the plasma discharge, and then the mixed gas of argon and oxygen is introduced.

Carrier concentration in the amorphous film 41 to be a channel may be controlled by changing a flow ratio between argon and oxygen during oxide formation.

After the amorphous film 41 is formed, as shown in FIG. 4B, a low-melting point amorphous film 42A, including an oxide semiconductor having a melting point lower than that of the amorphous film 41, is formed by, for example, a sputtering method. Specifically, for example, a low-melting point amorphous film 42A made of IZO is formed by a DC sputtering method with IZO ceramics as a target, and a sputtering condition is controlled so that the low-melting point amorphous film 42A made of amorphous IZO is formed. In this way, a multilayer film 43A of the amorphous film 41 and the low-melting point amorphous film 42A is formed.

After the multilayer film 43A is formed, as shown in FIG. 4C, the multilayer film 43A is formed into a predetermined shape, for example, an island shape including the gate electrode 20 and the neighborhood thereof by, for example, photolithography and etching. Since either of the amorphous film 41 and the low-melting point amorphous film 42A is an amorphous film, wet etching may be performed using a mixed solution containing phosphoric acid, nitric acid and acetic acid, leading to reduction in cost.

After the multilayer film 43A is formed, as shown in FIG. 4D, anneal treatment A is applied to the low-melting point amorphous film 42A at, for example, about 200° C. to 400° C., so that the crystallized film 42 is formed. Consequently, an oxide semiconductor film 40 having a multilayer structure of the amorphous film 41 and the low-melting point amorphous film 42A is formed.

After the oxide semiconductor film 40 is formed, as shown in FIG. 5A, a molybdenum layer with a thickness of 50 nm, an aluminum layer with a thickness of 500 nm and a molybdenum layer with a thickness of 50 nm are sequentially formed on the crystallized layer 42 of the oxide semiconductor film 40 by, for example, a sputtering method, and thus a metal film 50A having a three-layer multilayer structure is formed.

Next, the metal film 50A having the multilayer structure is patterned by a wet etching method using a mixed solution containing phosphoric acid, nitric acid and acetic acid, and thus a source electrode 50S and a drain electrode 50D are formed as shown in FIG. 5B. Since the source electrode 50S and the drain electrode 50D (metal film 50A) are provided on the crystallized film 42, wet etching selectivity of the source and drain electrodes 50S and 50D (metal film 50A) to the oxide semiconductor film 40 is high. Accordingly, the source electrode 50S and the drain electrode 50D may be selectively etched while etching of the oxide semiconductor film 40 is suppressed.

After the source electrode 50S and the drain electrode 50D are formed, as shown in FIG. 5C, a protective film 60 made of the above material is formed by, for example, a plasma CVD method or a sputtering method. This is the end of manufacturing of the thin film transistor 1 shown in FIG. 1.

In this way, in the method of manufacturing the thin film transistor 1 of the embodiment, the multilayer film 43A of the amorphous film 41 including an oxide semiconductor and the low-melting point amorphous film 42A, including an oxide semiconductor having a melting point lower than that of the amorphous film 41, is formed, and then the multilayer film 43A is shaped by etching. Therefore, the multilayer film 43A may be easily processed into a predetermined shape by inexpensive wet etching. Moreover, the low-melting point amorphous film 42A is annealed to be formed into the crystallized film 42, the oxide semiconductor film 40 having the multilayer structure of the amorphous film 41 and the crystallized film 42 is thus formed, the metal film 50A is then formed on the crystallized film 42, and the metal film 50A is etched to form the source electrode 50S and the drain electrode 50D. Therefore, when the channel etch type is used, wet etching selectivity of the source and drain electrodes 50S and 50D to the oxide semiconductor film 40 may be made high. Accordingly, the thin film transistor may use a simple channel-etch-type configuration, leading to decrease in number of manufacturing steps.

### THIRD EMBODIMENT

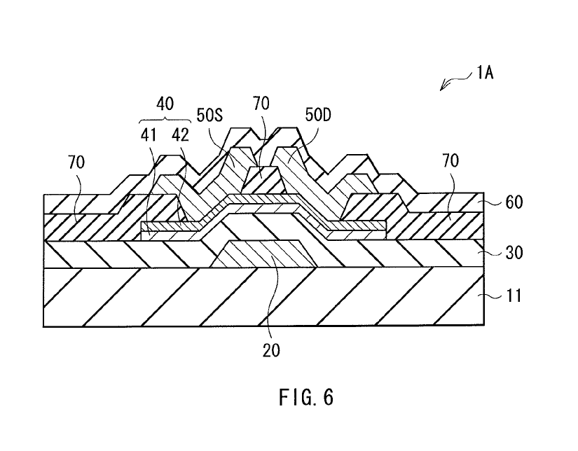

FIG. 6 shows a sectional configuration of a thin film transistor 1A according to a third embodiment. The thin film transistor 1A has the same configuration as in the first embodiment except that the transistor is etch-stopper-type TFT where an etching stopper layer 70 is provided on a channel region 40A, and respective ends of source and drain electrodes 50S and 50D are provided on the etching stopper layer 70. Therefore, corresponding components are described with the same reference numerals or signs.

The etching stopper layer 70, which functions as a channel protective film, has a thickness of, for example, 50 nm to 500 nm, specifically about 200 nm, and is configured of a single-layer film of a silicon oxide film, silicon nitride film or an aluminum oxide film, or a multilayer film of the films.

The thin film transistor 1A may be manufactured, for example, in the following way. The same steps as in the first embodiment are described with reference to FIGS. 2A to 2C and FIGS. 3A and 3B.

First, a gate electrode 20 and a gate insulating film 30 are formed on a substrate 11 according to the step as shown in FIG. 2A in the same way as in the first embodiment.

Next, a multilayer film 43 of an amorphous film 41 and a crystallized film 42 is formed on the gate insulating film 30 according to the step as shown in FIG. 2B in the same way as in the first embodiment.

Next, the multilayer film 43 is formed into a predetermined shape, for example, an island shape including the gate electrode 20 and the neighborhood thereof according to the step as shown in FIG. 2C in the same way as in the first embodiment. Consequently, an oxide semiconductor film 40 having a multilayer structure of the amorphous film 41 and the crystallized film 42 is formed.

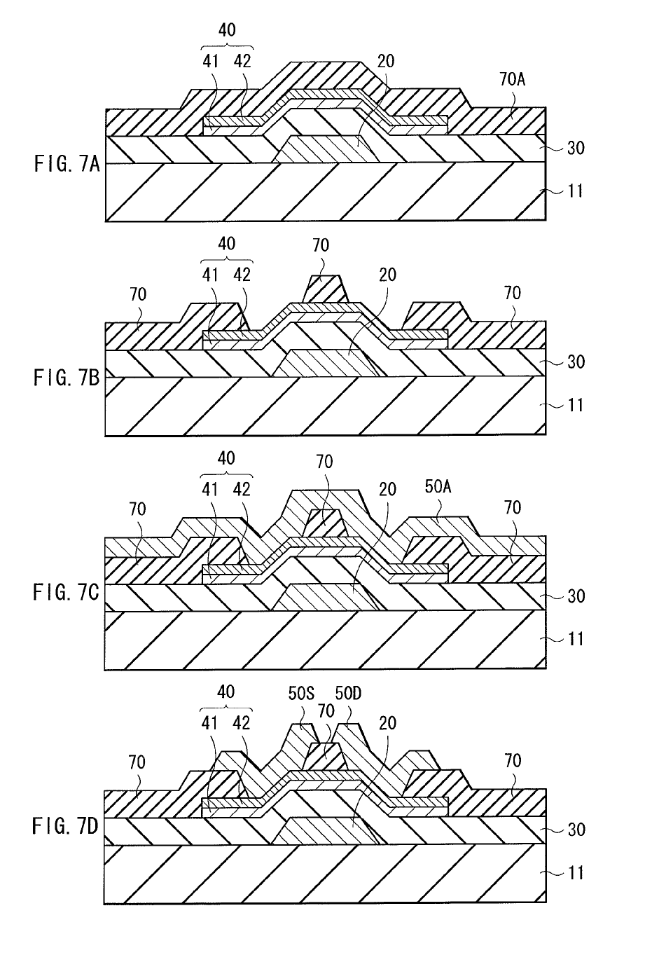

Then, as shown in FIG. 7A, an insulating film 70A, including a single-layer film of a silicon oxide film, a silicon nitride film or an aluminum oxide film, or a multilayer film of the films, is formed on the crystallized film 42 of the oxide semiconductor film 40 with a thickness of, for example, about 200 nm.

After the insulating film 70A is formed, as shown in FIG. 7B, the insulating film 70A is formed into a predetermined shape by, for example, photolithography and etching, and therefore the etching stopper layer 70 is formed. Since the etching stopper layer 70 (insulating film 70A) is provided on the crystallized film 42, wet etching selectivity of the etching stopper layer 70 (insulating film 70A) to the oxide semiconductor film 40 is high. Accordingly, the etching stopper layer 70 may be selectively etched while etching of the oxide semiconductor film 40 is suppressed, and consequently etching of the etching stopper layer 70 may be stopped on the channel region 40A. Even if a film such as an aluminum oxide film, which is hardly processed by dry etching, is used as the etching stopper layer 70, the film may be easily processed by wet etching.

After the etching stopper layer 70 is formed, as shown in FIG. 7C, a molybdenum layer with a thickness of 50 nm, an aluminum layer with a thickness of 500 nm and a molybdenum layer with a thickness of 50 nm are sequentially formed on the crystallized layer 42 of the oxide semiconductor film 40 by, for example, a sputtering method, and thus a metal film 50A having a three-layer multilayer structure is formed.

Next, the metal film 50A having the multilayer structure is patterned by a wet etching method using a mixed solution containing phosphoric acid, nitric acid and acetic acid, and thus the source electrode 50S and the drain electrode 50D are formed as shown in FIG. 7D.

After the source electrode 50S and the drain electrode 50D are formed, a protective film 60 made of the above material is formed by, for example, a plasma CVD method or a sputtering method. This is the end of manufacturing of the thin film transistor 1A shown in FIG. 6.

Operation and effects of the thin film transistor 1A are the same as in the first embodiment.

While the third embodiment has been described with a case where the multilayer film 43 of the amorphous film 41 and the crystallized film 42 is formed, and the multilayer film 43 is processed by etching in a step of forming the oxide semiconductor film 40 in the same way as in the first embodiment, it is allowed that a multilayer film 43A of an amorphous film 41 and a low-melting point amorphous film 42A is formed, the multilayer film 43A is processed by etching, and then the low-melting point amorphous film 42A is annealed to be formed into a crystallized film 42 in the same way as in the second embodiment.

### FOURTH EMBODIMENT

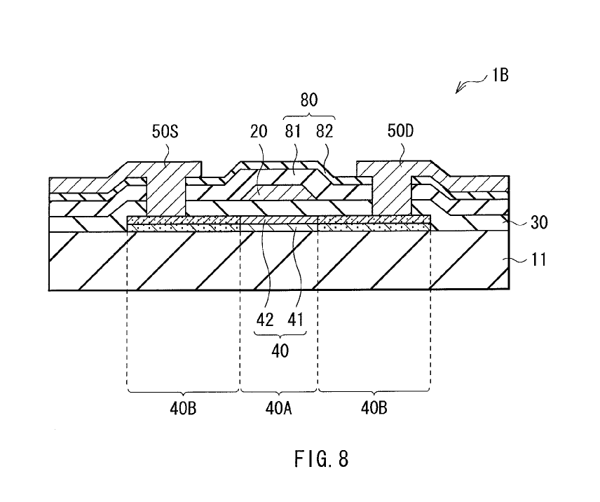

FIG. 8 shows a sectional configuration of a thin film transistor 1B according to a fourth embodiment. The thin film transistor 1B is a top gate TFT (staggered structure) where an oxide semiconductor film 40, a gate insulating film 30, a gate electrode 20, an interlayer insulating film 80, and a source electrode 50S and a drain electrode 50D are stacked in this order on a substrate 11. The thin film transistor 1B has the same configuration as in the first embodiment except the above. Therefore, corresponding components are described with the same reference numerals or signs.

The gate electrode 20, the gate insulating film 30, the source electrode 50S and the drain electrode 50D are configured in the same way as in the first embodiment.

The oxide semiconductor film 40 has an amorphous film 41 and a crystallized film 42 in this order from the substrate 11 side. In other words, in the embodiment, the crystallized film 42 is provided on an opposite side of the oxide semiconductor film 40 with respect to the gate electrode 20. However, since a transistor characteristic is controlled by the amorphous film 41, the film 41 functions to secure a uniform electric characteristic as in the first embodiment. Thickness and material of each of the amorphous film 41 and the crystallized film 42 are the same as in the first embodiment.

The oxide semiconductor film 40 has a channel region 40A facing the gate electrode 20, and has a low-resistance region 40B other than the channel region 40A. The low-resistance region 40B is introduced with hydrogen in atomic concentration of about 1% to be reduced in resistance so that on current of the thin film transistor 1B is reduced by parasitic resistance even in a region other than the channel region 40A. The source electrode 50S and the drain electrode 50D are provided to contact the crystallized film 42 in the low-resistance region 40B.

The interlayer insulating film 80 has a configuration where a silicon oxide film 81 with a thickness of about 300 nm and an aluminum oxide film 82 with a thickness of about 50 nm are sequentially stacked from a substrate 11 side.

The thin film transistor 1B may be manufactured, for example, in the following way.

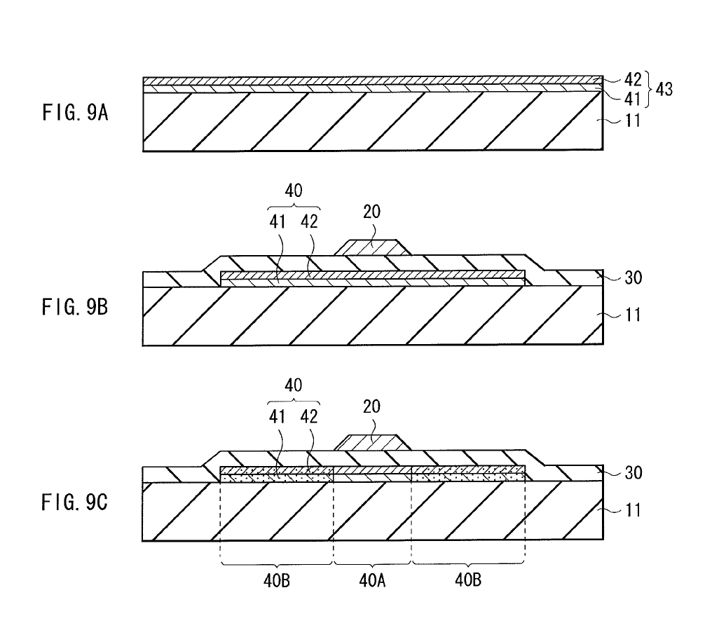

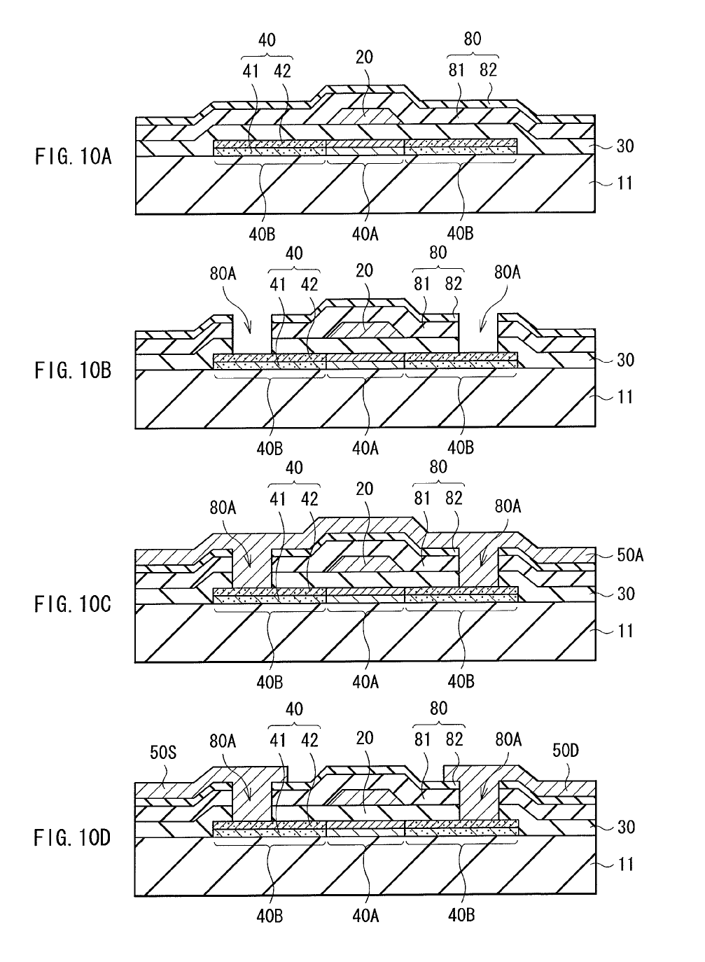

FIGS. 9A to 9C and FIGS. 10A to 10D show a method of manufacturing the thin film transistor 1B in a step sequence. First, as shown in FIG. 9A, the amorphous film 41, of which the thickness and the material are as described before, is formed on the substrate 11 by, for example, a sputtering method. Specifically, for example, an amorphous film 41 made of IGZO is formed on the gate insulating film 30 by plasma discharge using a mixed gas of argon and oxygen by means of a DC sputtering method with IGZO ceramics as a target. A vacuum chamber (not shown) is evacuated to an inner vacuum degree of 1×10-4 Pa or lower before the plasma discharge, and then the mixed gas of argon and oxygen is introduced.

Carrier concentration in the amorphous film 41 to be a channel may be controlled by changing a flow ratio between argon and oxygen during oxide formation.

Next, as shown in FIG. 9A, the crystallized film 42, of which the thickness and the material are as described before, is formed by, for example, a sputtering method. Specifically, for example, a crystallized film 42 made of IZO is formed by a DC sputtering method with IZO ceramics as a target. In this way, a multilayer film 43 of the amorphous film 41 and the crystallized film 42 is formed.

Next, as shown in FIG. 9B, the multilayer film 43 is formed into a predetermined shape, for example, an island shape including the gate electrode 20 and the neighborhood thereof by, for example, photolithography and etching. Consequently, the oxide semiconductor film 40 having a multilayer structure of the amorphous film 41 and the crystallized film 42 is formed.

Then, as shown in FIG. 9B, the gate insulating film 30, of which the thickness and the material are as described before, is formed over the whole surface on the substrate 11 and on the oxide semiconductor film 40 by, for example, a plasma CVD method as in the first embodiment.

After the gate insulating film 30 is formed, as shown in FIG. 9B, a gate electrode 20, of which the thickness and the material are as described before, is formed on the gate insulating film 30 in an overlapping position with the oxide semiconductor film 40 in the same way as in the first embodiment.

After the gate electrode 20 is formed, as shown in FIG. 9C, hydrogen in atomic concentration of, for example, about 1% is introduced into a region of the oxide semiconductor film 40 other than a region corresponding to the gate electrode 20 by plasma treatment containing hydrogen gas by means of a plasma CVD method or the like, ion doping, or ion injection. Consequently, in the oxide semiconductor film 40, the channel region 40A is formed to face the gate electrode 20, and the low-resistance region 40B introduced with hydrogen is formed over a region other than the channel region 40A.

After the low-resistance region 40B is formed, as shown in FIG. 10A, the silicon oxide film 81 and the aluminum oxide film 82, each film having the above thickness, are stacked by, for example, a plasma CVD method or a sputtering method, so that the interlayer insulating film 80 is formed.

After the interlayer insulating film 80 is formed, as shown in FIG. 10B, connection holes 80A are provided in the interlayer insulating film 80 and the gate insulating film 30 by, for example, etching, so that the crystallized layer 42 of the oxide semiconductor film 40 is exposed in the connection holes 80A. Since the interlayer insulating film 80 and the gate insulating film 30 are provided on the crystallized layer 42, etching rate of the crystallized layer 42 is adequately low compared with the interlayer insulating film 80 and the gate insulating film 30, and thus wet etching selectivity of the interlayer insulating film 80 and the gate insulating film 30 to the oxide semiconductor film 40 is high. Accordingly, the interlayer insulating film 80 and the gate insulating film 30 may be selectively etched while etching of the oxide semiconductor film 40 is suppressed, and consequently the connection holes 80A may be easily formed. In addition, the aluminum oxide film 82, which is hardly processed by dry etching, may be easily processed by wet etching.

Next, as shown in FIG. 10C, a molybdenum layer with a thickness of 50 nm, an aluminum layer with a thickness of 500 nm and a molybdenum layer with a thickness of 50 nm are sequentially formed on the interlayer insulating film 80 and on the crystallized layer 42 in the openings 80A by, for example, a sputtering method, and thus a metal film 50A having a three-layer multilayer structure is formed.

Next, the metal film 50A having the multilayer structure is patterned by a wet etching method using a mixed solution containing phosphoric acid, nitric acid and acetic acid, and thus the source electrode 50S and the drain electrode 50D are formed as shown in FIG. 10D. This is the end of manufacturing of the thin film transistor 1B shown in FIG. 8.

Operation and effects of the thin film transistor 1B are the same as in the first embodiment.

While the fourth embodiment has been described with a case where the multilayer film 43 of the amorphous film 41 and the crystallized film 42 is formed, and the multilayer film 43 is processed by etching in a step of forming the oxide semiconductor film 40 in the same way as in the first embodiment, it is allowed that a multilayer film 43A of an amorphous film 41 and a low-melting point amorphous film 42A is formed, and the multilayer film 43A is processed by etching, and then the low-melting point amorphous film 42A is annealed to be formed into a crystallized film 42 in the same way as in the second embodiment.

### APPLICATION EXAMPLE 1

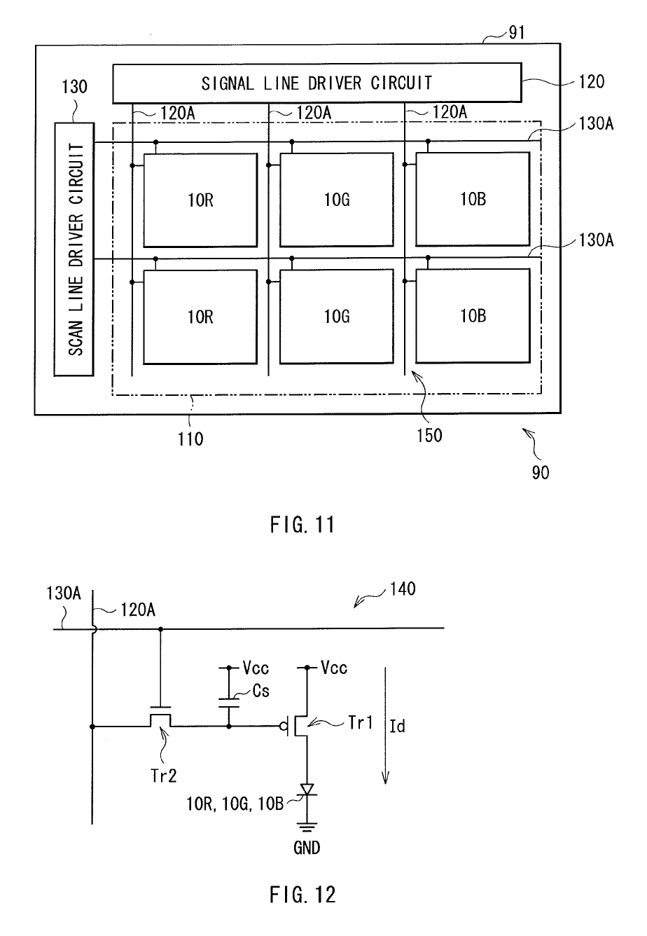

FIG. 11 shows a circuit configuration of a display device having the thin film transistor 1 as a drive element. A display device 90 is, for example, a liquid crystal display or an organic EL display, where a plurality of pixels 10R, 10G and 10B arranged in a matrix and various driver circuits for driving the pixels 10R, 10G and 10B are formed on a drive panel 91. The pixels 10R, 10G and 10B are liquid crystal display elements or organic EL elements emitting color light of red (R), green (G) and blue (B), respectively. A display region 110 is configured of a plurality of pixels with the three pixels 10R, 10G and 10B as one pixel. The driver circuits including, for example, a signal line driver circuit 120 and a scan line driver circuit 130 as drivers for video display and a pixel driver circuit 150 are provided on the drive panel 91. The drive panel 91 is attached with a not-shown sealing panel for sealing the pixels 10R, 10G and 10B and the driver circuits.

FIG. 12 is an equivalent circuit diagram of the pixel driver circuit 150. The pixel driver circuit 150 is an active driver circuit having transistors Tr1 and Tr2 being the thin film transistor 1, 1A or 1B each. A capacitor Cs is provided between the transistors Tr1 and Tr2, and the pixel 10R (or pixel 10G or 10B) is connected in series to the transistor Tr1 between a first power line (Vcc) and a second power line (GND). In such a pixel driver circuit 150, a plurality of signal lines 120A are arranged in a column direction, and a plurality of scan lines 130A are arranged in a row direction. Each signal line 120A is connected to the signal line driver circuit 120 that supplies an image signal to a source electrode of the transistor Tr2 via the signal line 120A. Each scan line 130A is connected to the scan line driver circuit 130 that sequentially supplies scan signals to gate electrodes of the transistors Tr2 via the scan lines 130A. Such a display device 90 may be mounted on, for example, electronic units as exemplified in the following application examples 2 to 6.

### APPLICATION EXAMPLE 2

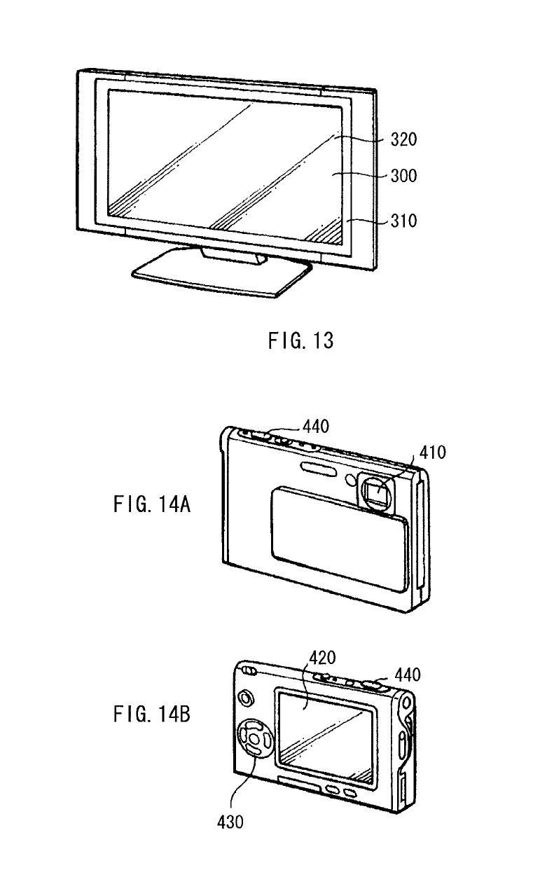

FIG. 13 shows appearance of a television apparatus. The television apparatus has, for example, an image display screen 300 including a front panel 310 and a filter glass 320.

### Application Example 3

FIGS. 14A and 14B show appearance of a digital camera. The digital camera has, for example, a light emitting section for flash 410, a display 420, a menu switch 430 and a shutter button 440.

### APPLICATION EXAMPLE 4

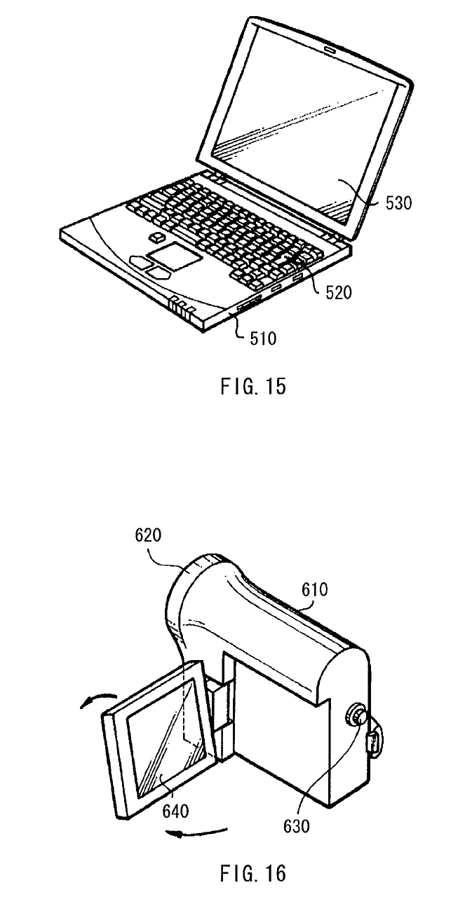

FIG. 15 shows appearance of a notebook personal computer. The notebook personal computer has, for example, a body 510, a keyboard 520 for input operation of letters and the like, and a display 530 for displaying images.

### APPLICATION EXAMPLE 5

FIG. 16 shows appearance of a video camera. The video camera has, for example, a body 610, an object-shooting lens 620 provided on a front side-face of the body 610, a start/stop switch 630 for shooting, and a display 640.

### APPLICATION EXAMPLE 6

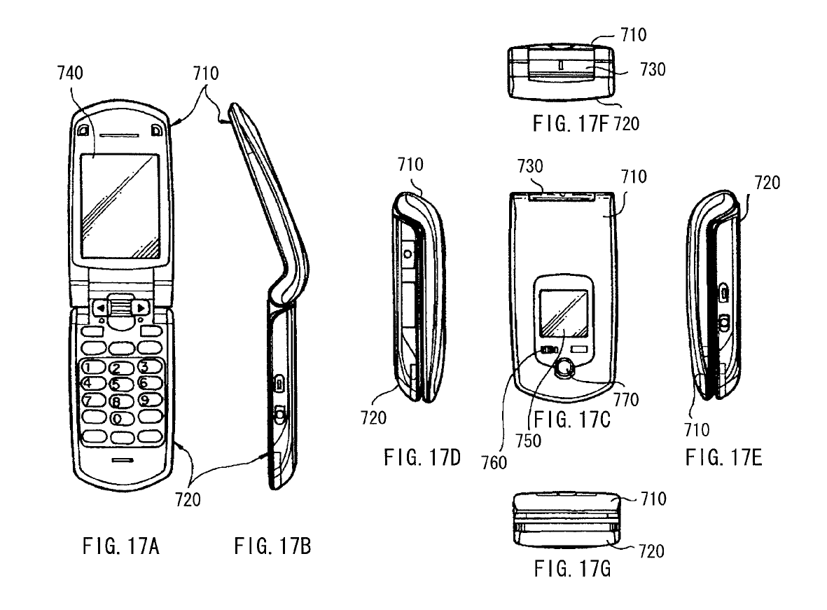

FIGS. 17A to 17G show appearance of a mobile phone. For example, the mobile phone is assembled by connecting an upper housing 710 to a lower housing 720 by a hinge 730, and has a display 740, a sub display 750, a picture light 760, and a camera 770.

While the application has been described with several embodiments hereinbefore, the application is not limited to the embodiments, and various modifications and alterations may be made. For example, the material and thickness of each layer, or the deposition method and the deposition condition of the layer described in the embodiments are not limitative, and other materials and thickness or other deposition methods and deposition conditions may be used.

Furthermore, the application may be applied not only to the liquid crystal display or the organic EL display, but also to display devices using other display elements such as an electrodeposition or electrochromic display element.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A thin film transistor comprising:
a gate electrode;
an oxide semiconductor film having a multilayer structure of an amorphous film and a crystallized film; and
a source electrode and a drain electrode provided to contact the crystallized film.

2. The thin film transistor according to claim 1,
wherein the gate electrode, a gate insulating film, the oxide semiconductor film, and the source electrode and the drain electrode are stacked in this order on a substrate, and
the oxide semiconductor film has the amorphous film and the crystallized film in this order from a side of the gate electrode.

3. The thin film transistor according to claim 2,
wherein the oxide semiconductor film has a channel region facing the gate electrode, and
an end of the source electrode and an end of the drain electrode are provided on the channel region.

4. The thin film transistor according to claim 2,
wherein the oxide semiconductor film has a channel region facing the gate electrode,
an etching stopper layer is provided on the channel region, and
an end of the source electrode and an end of the drain electrode are provided on the etching stopper layer.

5. The thin film transistor according to claim 1,
wherein the oxide semiconductor film, a gate insulating film, the gate electrode, an interlayer insulating film, and the source electrode and the drain electrode are stacked in this order on a substrate, and
the oxide semiconductor film has the amorphous film and the crystallized film in this order from a side of the substrate.

6. The thin film transistor according to claim 5,
wherein the oxide semiconductor film has a channel region facing the gate electrode and has a low-resistance region other than the channel region, and
the source electrode and the drain electrode are provided to contact the crystallized film in the low-resistance region.

7. A method of manufacturing a thin film transistor comprising:
forming a gate electrode on a substrate;
forming a gate insulating film on the gate electrode;
forming a multilayer film of an amorphous film including an oxide semiconductor and a crystallized film including an oxide semiconductor in this order on the gate insulating film;
shaping the multilayer film by etching to form an oxide semiconductor film having a multilayer structure of the amorphous film and the crystallized film; and
forming a metal film on the crystallized film, and etching the metal film to form a source electrode and a drain electrode.

8. A method of manufacturing a thin film transistor comprising:
forming a gate electrode on a substrate;
forming a gate insulating film on the gate electrode;
forming a multilayer film of an amorphous film including an oxide semiconductor and a low-melting point amorphous film in this order on the gate insulating film, the low-melting point amorphous film including an oxide semiconductor having a lower melting point than that of the amorphous film,;
shaping the multilayer film by etching;
annealing the low-melting point amorphous film to be formed into a crystallized film so as to form an oxide semiconductor film having a multilayer structure of the amorphous film and the crystallized film; and
forming a metal film on the crystallized film, and etching the metal film to form a source electrode and a drain electrode.

9. A display device comprising:
thin film transistors and pixels,
wherein each of the thin film transistors includes
a gate electrode,
an oxide semiconductor film having a multilayer structure of an amorphous film and a crystallized film, and
a source electrode and a drain electrode provided to contact the crystallized film.
